(19) United States
(12) Patent Application Publication
(10) Pub. No.: US 2016/0064269 A1
(43) Pub. Date: Mar. 3, 2016

(54) SEMICONDUCTOR DEVICE AND MANUFACTURING METHOD THEREOF

(71) Applicant: Kabushiki Kaisha Toshiba, Minato-ku (JP)

(72) Inventor: Masaaki HATANO, Yokkaichi (JP)

(73) Assignee: Kabushiki Kaisha Toshiba, Minato-ku (JP)

(21) Appl. No.: 14/568,286

(22) Filed: Dec. 12, 2014

Related U.S. Application Data
(60) Provisional application No. 62/044,671, filed on Sep. 2, 2014.

(51) Int. Cl. H01L 21/768; H01L 23/532

(52) U.S. Cl. CPC H01L 21/7682; H01L 23/5329; H01L 23/53238; H01L 21/76843

(57) ABSTRACT

A semiconductor device according to an embodiment includes a first wire and a second wire, a bottom nitride film, a side nitride film, and a top layer. The first and second wires are arranged on a base layer. The bottom nitride film is arranged on the base layer between the first and second wires. The side nitride film is respectively arranged on side surfaces of the first and second wires. The top layer is arranged on the first and second wires. An air gap exists between the first and second wires. The air gap is enclosed by the bottom nitride film, the side nitride film, and the top layer in a cross section orthogonal to an extending direction of the wires.

### CROSS REFERENCE TO RELATED APPLICATIONS

This application is based upon and claims the benefit of priority from the prior U.S. Provisional Patent Application No. 62/044,671 filed on Sep. 2, 2014, the entire contents of which are incorporated herein by reference.

### FIELD

Embodiments relate to a semiconductor device and a manufacturing method thereof.

### BACKGROUND

With recent downscaling of semiconductor devices, a semiconductor device having air gaps between wires has been proposed. The air gaps suppress an increase in the interwire parasitic capacitance associated with narrowing of the wiring pitch and reduce a wiring delay due to a time constant RC depending on an interwire parasitic capacitance C and a wiring resistance R.

When such a semiconductor device is to be manufactured, interlayer insulating films are formed on a base layer and wiring trenches are formed in the interlayer insulating films at a predetermined interval. Next, a barrier metal film and metal wires are sequentially formed in the wiring trenches and then excess wire metal and barrier materials attached to the outside of the recess are removed by CMP (Chemical Mechanical Planarization). The interlayer insulating films between the wires are then removed by wet etching, thereby forming the air gaps.

In the conventional manufacturing method of a semiconductor device, however, the metal wires may be peeled (lifted off) due to exposure of the barrier metal to a chemical solution and dissolution thereof during wet etching.

Therefore, a semiconductor device and a manufacturing method thereof that suppress peeling of the wires during formation of the air gaps are demanded.

### BRIEF DESCRIPTION OF THE DRAWINGS

FIGS. 1A and 1B are a plan view and a cross-sectional view schematically showing an example of a configuration of a semiconductor device 1 according to a first embodiment;

FIGS. 2 to 9B are cross-sectional views and plan views showing an example of a manufacturing method of the semiconductor device 1 according to the first embodiment;

FIGS. 10A to 10D are a plan view and cross-sectional views schematically showing an example of a configuration of the semiconductor device 1 according to a second embodiment;

FIGS. 11A to 12D are plan views and cross-sectional views showing an example of a manufacturing method of the semiconductor device 1 according to the second embodiment; and

FIGS. 13A and 13B are plan views schematically showing an example of a configuration of the semiconductor device 1 according to a third embodiment.

### DETAILED DESCRIPTION

Embodiments will now be explained with reference to the accompanying drawings. The present invention is not limited to the embodiments.

According to one embodiment, a semiconductor device includes a first wire and a second wire, a bottom nitride film, side nitride films, and a top layer. The first and second wires are arranged on a base layer. The bottom nitride film is arranged on the base layer between the first and second wires. The side nitride films are respectively arranged on side surfaces of the first and second wires. The top layer is arranged on the first and second wires. An air gap exists between the first and second wires. The air gap is enclosed by the bottom nitride film, the side nitride film, and the top layer in a cross section orthogonal to an extending direction of the wires.

### First Embodiment

### Semiconductor Device 1

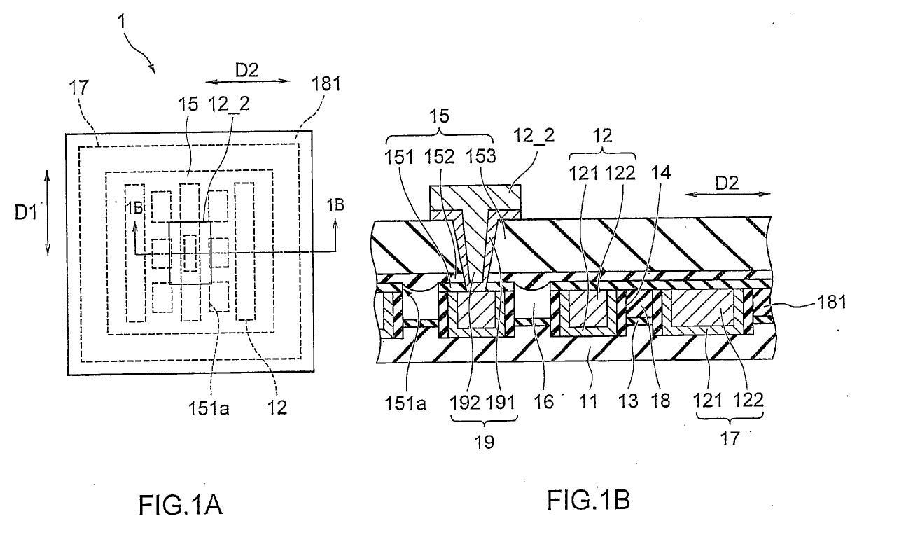

FIG. 1A is a plan view schematically showing an example of a configuration of a semiconductor device 1 according to a first embodiment. FIG. 1B is a cross-sectional view along a line 1B-1B in FIG. 1A.

As shown in FIGS. 1A and 1B, the semiconductor device 1 includes a base layer 11, wires 12 as a first wire and a second wire, a bottom nitride film 13, a side nitride film 14, and a top layer 15. The semiconductor device 1 further includes via contacts 19 and top layer wires 12_2.

### (Base Layer 11)

The base layer 11 is, for example, a SiO₂ film formed on a semiconductor substrate (not shown). The base layer 11 can be the oxide films other than the SiO₂ films or the insulating films other than oxide films.

The base layer 11 can be, for example, an interlayer dielectric film formed above a cell array of a NAND flash memory. The base layer 11 can be formed above a cell array of a flash memory other than the NAND flash memory, such as a NOR flash memory or can be formed above a semiconductor element other than flash memories.

### (Wires 12)

A plurality of wires 12 are arranged on the base layer 11 and extend in a direction D1. The respective wires 12 are arrayed in a direction D2 orthogonal to the direction D1 and adjoin each other at a predetermined interval. The interval between the wires 12 is such a size that openings 151a explained later can be formed by a lithography technique.

Each of the wires 12 includes a barrier metal film 121 and a metal wire 122.

The barrier metal film 121 is arranged, for example, to prevent diffusion of metal materials of the metal wire 122 to interlayer insulating films 18 explained later. The barrier metal film 121 is arranged on the base layer 11 to be in contact with the side nitride film 14. The barrier metal film 121 is one of a Ti film, a TiN film, and a stacked film including the Ti film and the TiN film. With the Ti-based barrier metal film 121, the material cost can be reduced relative to a Ta-based barrier metal film. Other advantages of the Ti-based barrier metal film are disclosed also in U.S. Pat. No. 7,351,656.

The metal wire 122 is arranged on the barrier metal film 121 to be inscribed in the barrier metal film 121 on bottom and side surfaces thereof.

The metal wire 122 is, for example, a Cu wire. Because the Cu wire can reduce a wiring resistance compared to an Al wire, a wiring delay can be reduced. If a Cu-diffusion preventing function can be ensured, the barrier metal film 121 is preferably as thin a film as possible in view of reduction in the wiring resistance.

### (Bottom Nitride Film 13)

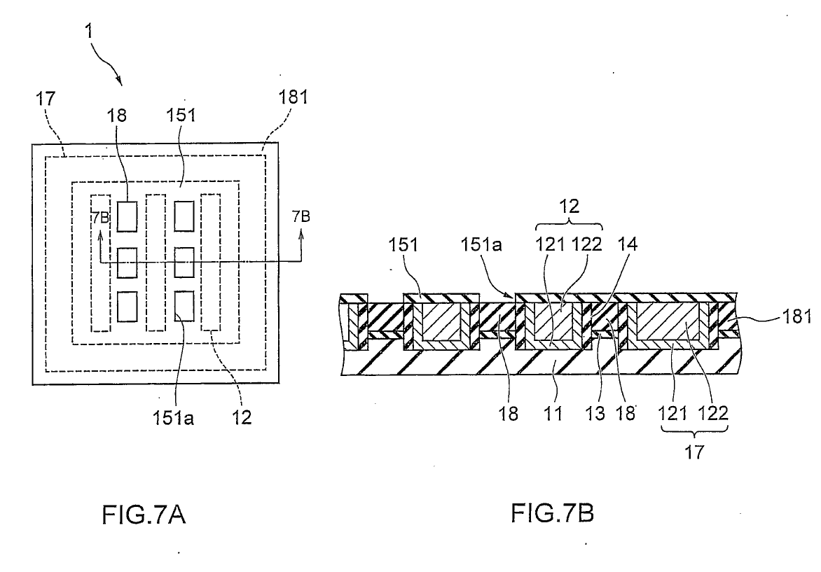

The bottom nitride film 13 is arranged on the base layer 11 between the adjacent wires 12. Each portion of the bottom nitride film 13 is connected on both ends thereof in the direction D2 to a pair of portions of the side nitride film 14 facing each other across an air gap 16. The bottom nitride film 13 is arranged at an upper position than a bottom end of the barrier metal film 121. Bottom ends of the side nitride film 14 arranged on the side surfaces of the barrier metal film 121 are thereby located at lower positions than the bottom nitride film 13 and thus no space is formed between the bottom nitride film 13 and the side nitride film 14. Accordingly, during etching of the interlayer insulating films 18, the base layer 11 is not etched from between the bottom nitride film 13 and the side nitride film 14, which can suppress an etchant from reaching bottom portions of the barrier metal film 121. As a result, the air gaps 16 enclosed by the nitride films 13 and 14 can be reliably obtained while lift-off of the barrier metal film 121 and the wires 122 is suppressed. The bottom nitride film 13 is, for example, a Si₃N₄ film. The bottom nitride film 13 can be a nitride film other than the Si₃N₄ film as long as it has a resistance to a chemical solution that wet etches the interlayer insulating films 18 (see FIG. 7) between the wires 12, which will be explained later.

### (Side Nitride Film 14)

The side nitride film 14 is arranged on the side surfaces of the wires 12. More specifically, the side nitride film 14 is formed entirely on outer side surfaces of the barrier metal film 121.

The side nitride film 14 is, for example, a Si₃N₄ film. The side nitride film 14 can be a nitride film other than the Si₃N₄ film as long as it has a resistance to the etchant for the wet etching similarly to the bottom nitride film 13. If a function to suppress the etchant from reaching the bottom portions of the barrier metal film 121 can be ensured, the side nitride film 14 is preferably as thin a film as possible in view of reduction in the wiring resistance similarly to the barrier metal film 121.

### (Air Gaps 16)

The bottom nitride film 13, the side nitride film 14, and the top layer 15 enclose the air gaps 16 located between the adjacent wires 12 in a cross section orthogonal to the direction D1. That is, the air gaps 16 enclosed by the bottom nitride film 13, the side nitride film 14, and the top layer 15 in a cross section orthogonal to the direction D1 exist, between the first and second wires 12.

The air gaps 16 may also be referred such as spaces, cavities, or air layers. Because the interwire parasitic capacitance can be suppressed by the air gaps 16, the wiring delay can be reduced.

### (Top Layer 15)

The top layer 15 is arranged on the wires 12 and the air gaps 16. The top layer 15 includes a top nitride film 151, an air gap film 152, and an insulating layer 153.

The top nitride film 151 is arranged on the wires 12 and the side nitride film 14 so as to cover top surfaces of the wires 12 and top end faces of the side nitride film 14. The top nitride film 151 has a plurality of openings 151a connected to the air gaps 16, respectively. The openings 151a are provided at an interval in the directions D1 and D2. The top nitride film 151 is, for example, a Si₃N₄ film. The top nitride film 151 can be, for example, a silicon carbide (SiC) film or a nitrogen-added silicon carbide (SiCN) film as long as it has a resistance to the etchant for the wet etching similarly to the bottom nitride film 13.

The air gap film 152 is arranged on the air gaps 16 and the top nitride film 151 to close the openings 151a. The air gap film 152 thereby ensures a shape of the air gaps 16. A material and a formation method of the air gap film 152 have a coverage performance that is reduced to such an extent as to suppress the air gap film 152 from entering the air gaps 16 through the openings 151a. One example of the material is SiO₂. One example of the formation method is plasma CVD (Chemical Vapor Deposition). The insulating layer 153 is arranged on the air gap film 152. The insulating layer 153 is, for example, a SiO₂ layer. The insulating layer 153 can be an oxide layer other than the SiO₂ layer.

### (Via Contacts 19)

The via contacts 19 are arranged inside of via holes passing through a top surface of the insulating film 153 and top surfaces of the metal wires 122, respectively. Each of the via contacts 19 has a barrier metal 191 formed on an internal surface of the corresponding via hole and a contact plug 192 formed inside of the barrier metal 191. The barrier metal 191 is, for example, a Ti-based metal film. The contact plug 192 is, for example, Al. The via contacts 19 electrically connect the wires 12 with the top layer wires 12_2, respectively. The semiconductor device 1 has a structure that is obtained by embedding metals of the via contacts 19 and the top layer wires 12_2 in the insulating film 153 at the same time and forming the top layer wires 12_2 by etching such as a RIE (Reactive Ion Etching) method, a dual damascene structure, or a single damascene structure that is obtained by forming the via contacts 19 and the top layer wires 12_2 individually by metal wire formation, and can have multilayer wires repeatedly stacked. As long as a circuit design resistance allows, the contact plugs 192 and the top layer wires 12_2 can be other metallic materials such as W.

### (Guard Ring 17)

A guard ring 17 is arranged outside of a formation area of the wires 12 so as to surround all the wires 12 in the directions D1 and D2.

The guard ring 17 has the barrier metal film 121 and the metal wire 122 similarly to the wires 12. The guard ring 17 prevents the chemical solution from flowing in peripheral circuits outside the formation area of the wires 12 and etching the peripheral circuits during wet etching of the interlayer insulating films 18 between the wires 12, which will be explained later.

Interlayer insulating films 181 are arranged outside of the guard ring 17. The interlayer insulating films 181 can enhance the strength of the semiconductor device 1. If an air gap is provided instead of the interlayer insulating films 181, the top nitride film 151 may be deposited between wires of the peripheral circuits outside of the guard ring 17 so as to fill the air gap in some cases. In these cases, the deposited top nitride film 151 increases the parasitic capacitance between the wires of the peripheral circuits. In contrast thereto, according to the first embodiment, because the interlayer insulating films 181 are located outside of the guard ring 17, an increase in the parasitic capacitance between the wires of the peripheral circuits can be structurally avoided. The interlayer insulating films 181 are the same material as the interlayer insulating films 18 between the wires 12 and are, for example, SiO₂ films. The interlayer insulating films 181 can be the oxide films other than the SiO₂ films or can be the insulating films other than oxide films.

As described above, the semiconductor device 1 according to the first embodiment can enclose the air gaps 16 with the bottom nitride film 13, the side nitride film 14, and the top layer 15 having the resistance to the chemical solution for wet etching. Accordingly, as explained later, when the air gaps 16 are formed by wet etching of the interlayer insulating films 18 between the wires 12, the barrier metal film 121 of the wires 12 can be prevented from being exposed to the chemical solution. As a result, peeling of the barrier metal film 121 during formation of the air gaps 16 can be suppressed.

### (Manufacturing Method of Semiconductor Device 1)

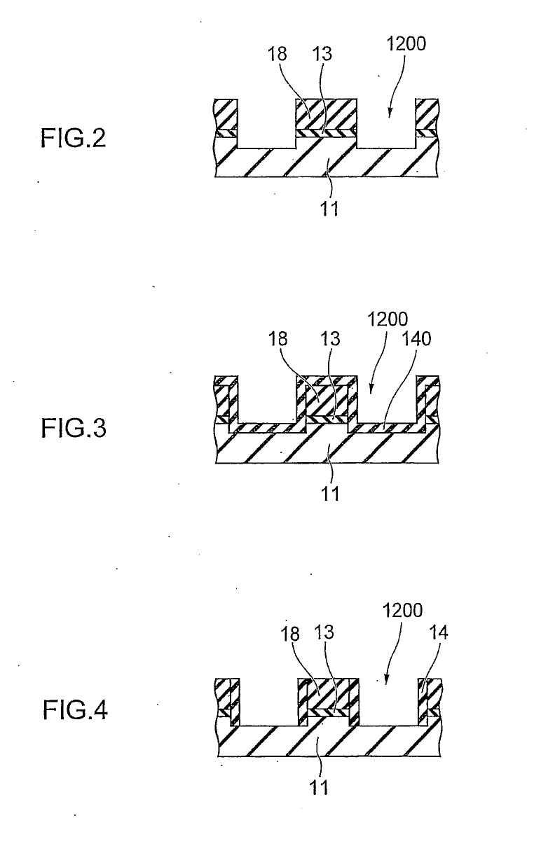

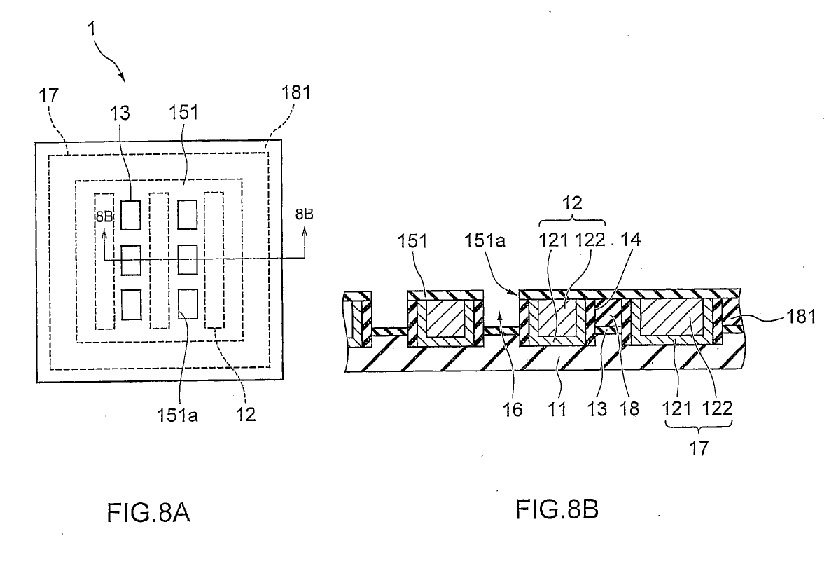

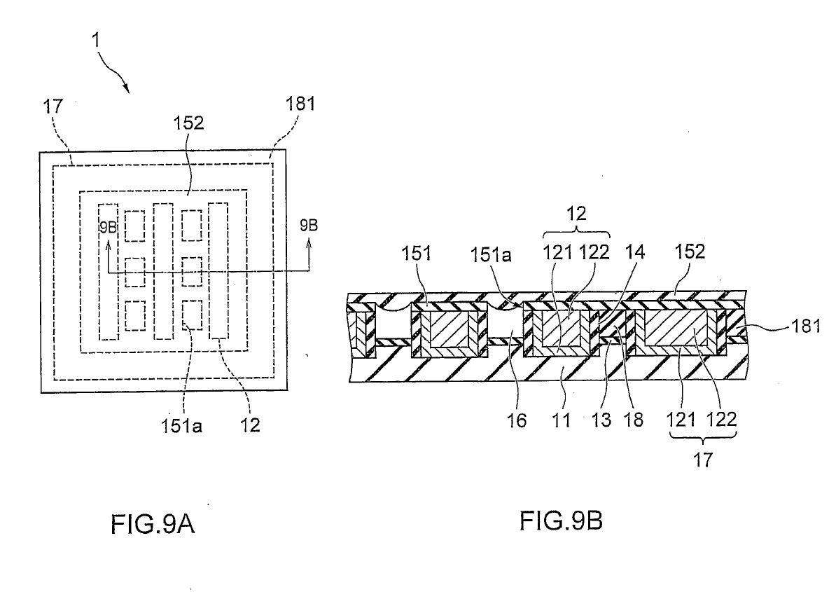

FIGS. 2 to 9B are cross-sectional views and plan views showing an example of a manufacturing method of the semiconductor device 1 according to the first embodiment. FIG. 7A is a plan view showing a formation step of the openings 151a. FIG. 7B is a cross-sectional view along a line 7B-7B in FIG. 7A. FIG. 8A is a plan view showing a wet etching step. FIG. 8B is a cross-sectional view along a line 8B-8B in FIG. 8A. FIG. 9A is a plan view showing a formation step of the air gap film 152. FIG. 9B is a cross-sectional view along a line 9B-9B in FIG. 9A.

In the manufacturing method according to the first embodiment, semiconductor elements are first formed on a semiconductor substrate and an interlayer dielectric film that covers the semiconductor elements is formed on the semiconductor substrate. Next, as shown in FIG. 2, the bottom nitride film 13 is formed on the base layer 11 formed on the semiconductor substrate. The interlayer insulating films 18 and 181 as insulating films are then formed on the bottom nitride film 13. Next, wiring trenches 1200 (a first wiring trench and a second wiring trench) are formed in the bottom nitride film 13 and the interlayer insulating films 18 and 181. In the first embodiment, it is assumed that the width of the wiring trenches 1200 is equal to or larger than a lithography resolution. In this case, formation of the wiring trenches 1200 is performed by the lithography technique.

Next, as shown in FIG. 3, a base film 140 of the side nitride film 14 is formed on the wiring trenches 1200 and the interlayer insulating films 18.

The base film 140 is then entirely etched back with the side nitride film 14 left as shown in FIG. 4. The side nitride film 14 covering side surfaces of the wiring trenches 1200 is thereby obtained.

Next, as shown in FIG. 5, the wires 12 are formed in the wiring trenches 1200, respectively. Specifically, the barrier metal film 121 that covers bottom surfaces of the wiring trenches 1200 and side surfaces of the side nitride film 14 is first formed. The metal wires 122 are then formed on the barrier metal film 121. Seed Cu layers of the barrier metal film 121 and the metal wires 122 are formed by sputtering or CVD (Chemical Vapor Deposition) method or ALD (Atomic Layer Deposition) method or the like. Formation of the metal wires 122 is performed by a Cu plating process or the like. Furthermore, at the step shown in FIG. 5, the guard ring 17 is formed in the wiring trench 1200 in the same way as the formation method of the wires 12.

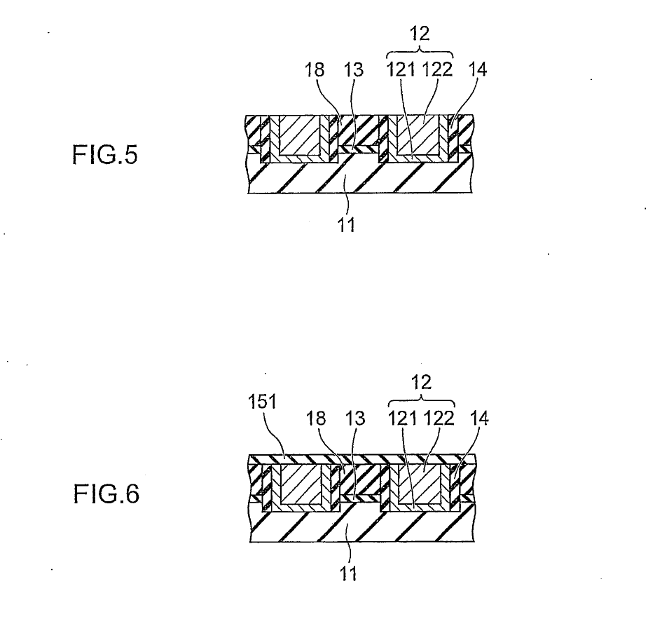

Next, as shown in FIG. 6, the top nitride film 151 is formed on the wires 12, the side nitride film 14, and the interlayer insulating films 18 located between the wires 12.

The openings 151a connected to the interlayer insulating films 18 between the wires 12 are then formed in the top nitride film 151 as shown in FIG. 7. Specifically, the openings 151a are formed in the top nitride film 151 located on top portions between the wires 12 using the lithography technique and an etching technique. The interlayer insulating films 181 are separated by the guard ring 17 from the portions of the interlayer insulating films 18 between the wires 12. While being connected to the portions of the interlayer insulating films 18 between the wires 12, the openings 151a are not connected to the interlayer insulating films 181 outside of the guard ring 17 and the portions of the interlayer insulating films 18 inside of the guard ring 17. Because the interval between the wires 12 is wider than the minimum feature size of the lithography technique, the openings 151a can be formed by the lithography technique. After the openings 151a are etched, opening widths and misalignments are adjusted so that the barrier metal film 121 is not exposed.

Next, as shown in FIG. 8, the portions of the interlayer insulating films 18 between the adjacent wires 12 are removed by wet etching, thereby forming the air gaps 16 between the adjacent wires 12.

At that time, the barrier metal film 121 of the wires 12 is separated from the interlayer insulating films 18 between the wires 12 by the bottom nitride film 13, the side nitride film 14, and the top nitride film 151. This prevents the barrier metal film 121 from being exposed to the chemical solution and being peeled by wet etching. Furthermore, the interlayer insulating films 181 outside of the guard ring 17 are not exposed to the chemical solution and left.

Next, as shown in FIG. 9, the air gap film 152 (a first top layer) is formed on the air gaps 16 and the top nitride film 151 to close the openings 151a. Formation of the air gap film 152 is performed by a film formation technique of a SiO₂ film (the plasma CVD method, for example) using P—SiH₄ or the like as a raw material gas.

After a normal film formation step of the insulating film 153 is then performed, the via contacts 19 are opened, metal film formation is performed for the via contacts 19 and the top layer wires 12_2, and the top layer wires 12_2 are formed by the RIE method.

With the steps mentioned above, the semiconductor device 1 shown in FIG. 1 can be obtained.

According to the first embodiment, while the air gaps 16 are formed of the bottom nitride film 13, the side nitride film 14, and the top layer 15, exposure of the barrier metal film 121 to the chemical solution for the wet etching can be prevented and thus peeling of the wires 12 during formation of the air gaps 16 can be suppressed.

### Second Embodiment

A second embodiment is explained next. In the explanations of the second embodiment, constituent elements corresponding to those in the first embodiment are denoted by like reference characters and redundant explanations will be omitted.

### (Semiconductor Device 1)

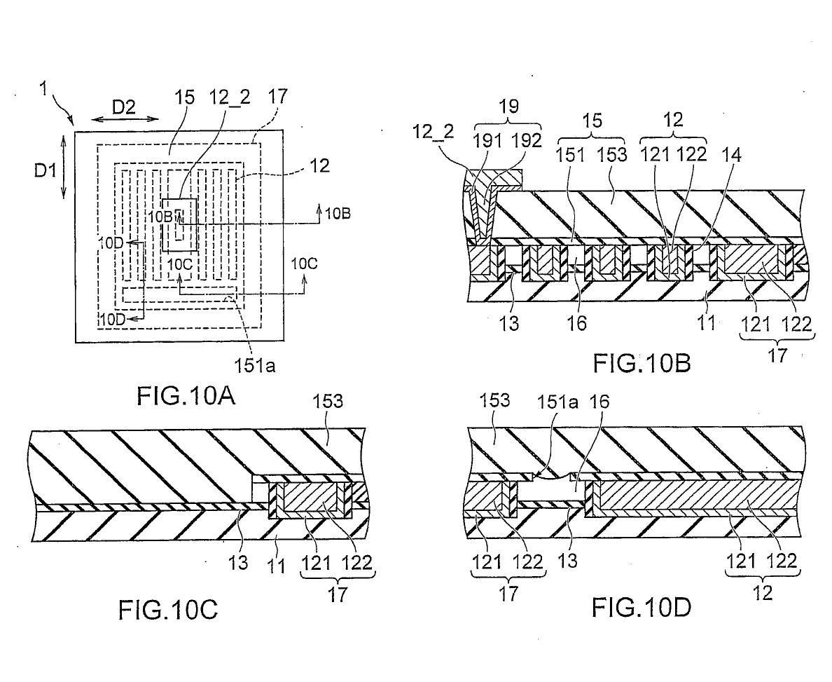

FIGS. 10A to 10D are plan views and cross-sectional views schematically showing an example of a configuration of the semiconductor device 1 according to the second embodiment. FIG. 10A is a plan view of the semiconductor device 1. FIG. 10B is a cross-sectional view along a line 10B-10B in FIG. 10A. FIG. 10C is a cross-sectional view along a line 10C-10C in FIG. 10A. FIG. 10D is a cross-sectional view along a line 10D-10D in FIG. 10A. The wires 12 in the second embodiment are finer than the wires 12 in the first embodiment. The width of the wires 12 in the second embodiment is, for example, about dozen nanometers to two dozen nanometers. Such wires 12 are, for example, bit lines of a NAND flash memory. The interval of the wires 12 in the second embodiment is smaller than the minimum size processable by lithography and etching in some cases.

Accordingly, in the semiconductor device 1 according to the second embodiment, it is difficult to form the openings on the top portions between the wires 12. Therefore, the semiconductor device 1 according to the second embodiment has the opening 151a outside of the wires 12 and inside of the guard ring 17 instead of having the openings on the top portions between the wires 12. Specifically, the semiconductor device 1 according to the second embodiment has the opening 151a connected to the portions of the interlayer insulating films 18 between the wires 12 in an area that is located outside of the formation area of the wires 12 and is equal to or larger than the minimum size processable by lithography and etching.

The semiconductor device 1 according to the second embodiment has the opening 151a at a position deviated from the portions between the wires 12, instead of having the openings on the portions between the wires 12. Accordingly, the possibility that a film of an upper layer of the opening 151a enters the air gaps 16 between the wires 12 through the opening 151a is low and the possibility that the film is deposited in the air gaps 16 between the wires 12 to increase, the interwire capacitance is low. Therefore, the semiconductor device 1 according to the second embodiment has a low necessity of forming the air gap film 152 having a reduced coverage performance on an upper layer of the opening 151a to suppress an increase in the interwire capacitance caused by deposition of the film of the upper layer of the opening 151a.

The semiconductor device 1 according to the second embodiment thus does not include the air gap film 152 and seals the opening 151a with the insulating film 153. The number of parts can be thereby reduced.

### (Manufacturing Method of Semiconductor Device 1)

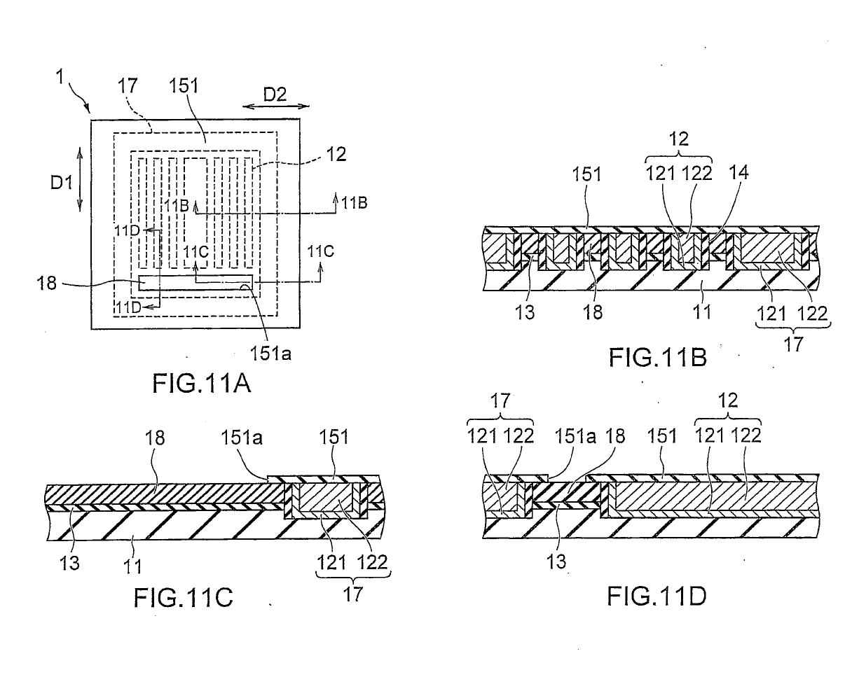

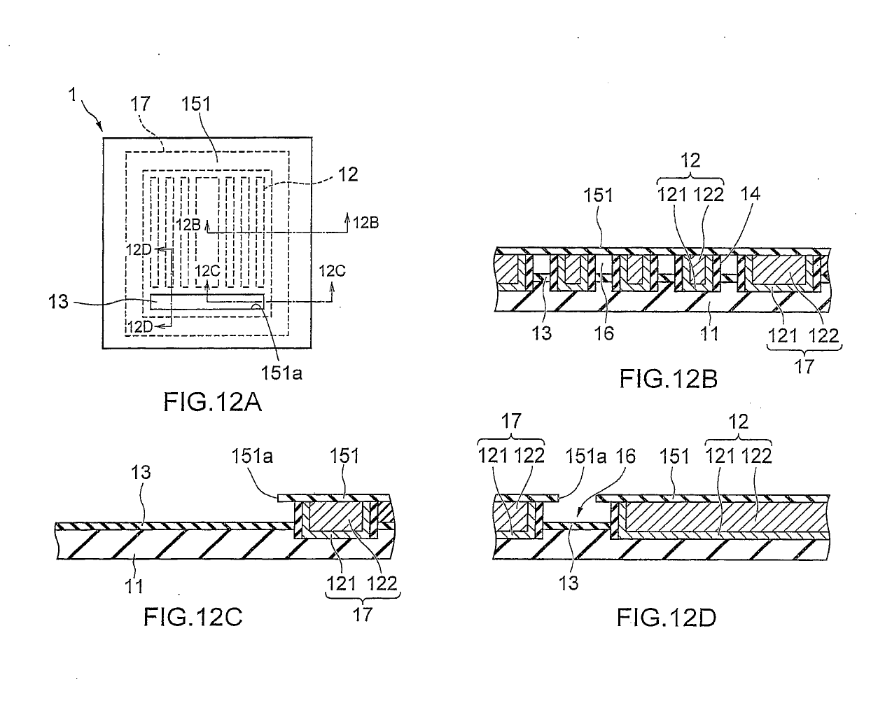

FIGS. 11A to 12D are plan views and cross-sectional views showing an example of a manufacturing method of the semiconductor device 1 according to the second embodiment. FIG. 11A is a plan view showing a formation step of the opening 151a. FIG. 11B is a cross-sectional view along a line 11B-11B in FIG. 11A. FIG. 11C is a cross-sectional view along a line 11C-11C in FIG. 11A. FIG. 11D is a cross-sectional view along a line 11D-11D in FIG. 11A. FIG. 12A is a plan view showing a wet etching step. FIG. 12B is a cross-sectional view along a line 12B-12B in FIG. 12A. FIG. 12C is a cross-sectional view along a line 12C-12C in FIG. 12A. FIG. 12D is a cross-sectional view along a line 12D-12D in FIG. 12A.

In the manufacturing method according to the second embodiment, because the width of the wiring trenches 1200 shown in FIG. 2 is smaller than a resolution limit of the lithography technique, the wiring trenches 1200 are formed using a sidewall processing technique.

Furthermore, in the manufacturing method according to the second embodiment, after the top nitride film 151 (a first top layer) is formed, the insulating film 153 is formed without forming the air gap film 152 (see FIG. 10). The number of manufacturing step can be thereby reduced.

Other steps can be identical to those in the first embodiment except for a formation pattern of the opening 151a explained below. In the manufacturing method according to the second embodiment, the opening 151a is formed on the top nitride films 151 at a position corresponding to outside of the wires 12 and inside of the guard ring 17 as shown in FIG. 11. The opening 151a can extend in the direction D2 so as to have equal distances from ends of all the wires 12 in the direction D1. While the opening 151a extending in the direction D2 is located at a lower position than the wires 12 in FIG. 10A, an identical opening can be arranged at an upper position than the wires 12. The portions of the interlayer insulating films 18 between the wires 12 thereby can be exposed to the chemical solution at the same time and thus efficiency and promptness of wet etching can be enhanced.

Next, the portions of interlayer insulating films 18 between the wires 12 are removed by wet etching, thereby forming the air gaps 16 between the wires 12 as shown in FIG. 12.

The insulating film 153, the via contacts 19, and the top layer wires 12_2 are then sequentially formed, thereby obtaining the semiconductor device 1 shown in FIG. 10. Because the opening 151a is located outside of the formation area of the wires 12, the insulating film 153 that seals the opening 151a does not significantly increase the interwire capacitance even if entering the opening 151a.

According to the second embodiment, even when the interval between the wires 12 is further narrowed relative to the first embodiment, peeling of the wires 12 during formation of the air gaps 16 can be suppressed. Application of the second embodiment to a wiring structure that will be further narrowed in the future is not excluded.

### Third Embodiment

A third embodiment is explained next. In the explanations of the third embodiment, constituent elements corresponding to those in the first and second embodiments are denoted by like reference characters and redundant explanations will be omitted.

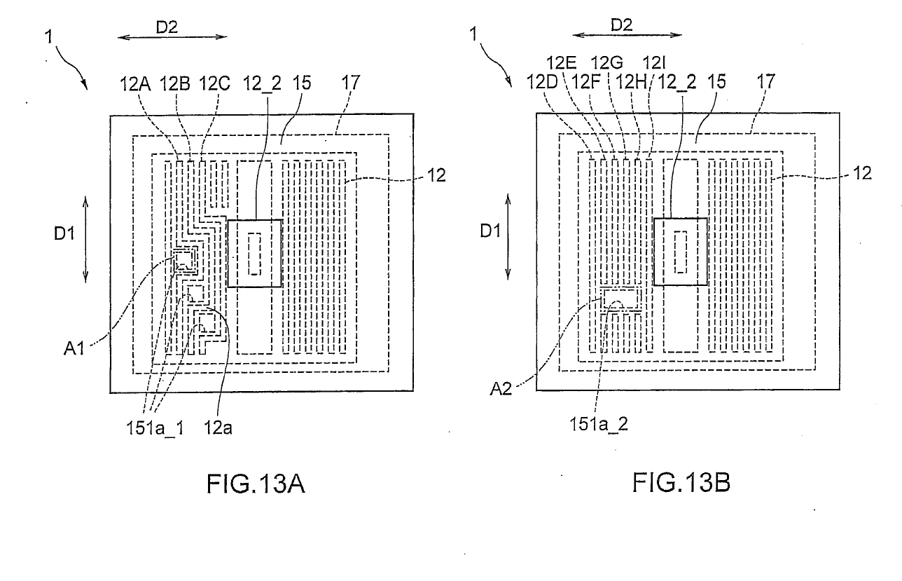

FIG. 13A is a plan view schematically showing an example of a configuration of the semiconductor device 1 according to the third embodiment. FIG. 13B is a plan view schematically showing a configuration of the semiconductor device 1 according to a modification of the third embodiment.

In the semiconductor device 1 shown in FIG. 10, because the interval between the wires 12 is smaller than the minimum size processable by lithography and etching (hereinafter, simply “minimum size”), no openings can be formed between the wires 12 and thus the opening 151a is formed outside of the formation area of the wires 12.

However, the openings can be formed inside of the formation area of the wires 12 depending on patterns of the wires 12 even when the interval between the wires 12 is fundamentally smaller than the minimum size.

For example, when some wires 12A to 12C have a portion 12a bending in the direction D2 as shown in FIG. 13A, an area A1 equal to or larger than the minimum size is sometimes ensured between the adjacent wires 12. Accordingly, openings 151a_1 are formed on the areas A1 in the third embodiment.

Furthermore, when some adjacent wires 12E to 12H are interrupted in the direction D1 as shown in FIG. 13B, an area A2 equal to or larger than the minimum size can be ensured between wires 12D and 12I on both sides of the wires 12E to 12H in some cases. Also in this case, an opening 151a_2 can be formed on the area A2.

In view of quickly spreading the chemical solution over the portions of interlayer insulating films 18 between the wires 12 and efficiently performing wet etching, if a plurality of the areas A1 or A2 equal to or larger than the minimum size can be ensured, it is desirable to form the openings 151a_1 or 151a_2 as many as possible for each area A1 or A2.

The semiconductor devices 1 shown in FIGS. 13A and 13B can have the air gap film 152 that closes the openings 151a_1 or 151a_2 as in the first embodiment. The semiconductor devices 1 shown in FIGS. 13A and 13B can be manufactured according to the manufacturing method described in the first embodiment except that the wiring trenches 1200 are formed using the sidewall processing technique.

According to the semiconductor devices 1 of the third embodiment, the openings 151a_1 or 151a_2 can be formed using spaces in the formation area of the wires 12. Therefore, the space for the opening 151a does not need to be actively provided outside of the formation area of the wires 12 as the second embodiment and thus the area of the semiconductor devices 1 can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first wire and a second wire arranged on a base layer;
a bottom nitride film arranged on the base layer between the first and second wires;
side nitride films respectively arranged on side surfaces of the first and second wires; and
a top layer arranged on the first and second wires, wherein
an air gap exists between the first and second wires, the air gap being enclosed by the bottom nitride film, the side nitride films, and the top layer in a cross section orthogonal to an extending direction of the first and second wires.

2. The device of claim 1, wherein
the first and second wires comprise a barrier metal film arranged on the base layer to be in contact with the side nitride film, and metal wires arranged on the barrier metal film, and
the barrier metal film is one of a Ti film, a TiN film, and a stacked film of the Ti film and the TiN film.

3. The device of claim 1, further comprising a guard ring surrounding the first and second wires.

4. The device of claim 1, wherein the top layer comprises a top nitride film.

5. The device of claim 4, wherein the top nitride film has an opening connected to the air gaps.

6. The device of claim 5, wherein the top layer further comprises an air gap film arranged on the air gaps and on the top nitride film in order to close the opening.

7. The device of claim 3, further comprising an insulating film outside of the guard ring.

8. The device of claim 1, wherein the bottom ends of the side nitride films are located at a position lower than the bottom nitride film.

9. A semiconductor device comprising:
a first wire and a second wire arranged on a base layer;
side nitride films respectively arranged on side surfaces of the first and second wires; and
a top layer arranged on the first and second wires, wherein
an air gap exists between the first and second wires, the air gap being enclosed by the side nitride films and the top layer in a cross section orthogonal to an extending direction of the first and second wires.

10. A manufacturing method of a semiconductor device, the method comprising:
forming a bottom nitride film on a base layer;
forming an insulating film on the bottom nitride film;
forming a first wiring trench and a second wiring trench in the insulating film, the bottom nitride film, and the base layer;
forming a side nitride film respectively covering side surfaces of the first and second wiring trenches;
forming a first wire in the first wiring trench;
forming a second wire in the second wiring trench; and
removing the insulating film and forming a first top layer in order to form an air gap between the first and second wires, the air gap being enclosed by the bottom nitride film, the side nitride film, and the first top layer in a cross section orthogonal to an extending direction of the first and second wires.

11. The method of claim 10, wherein
removing of the insulating film is performed by:
forming a top nitride film on the first and second wires, the side nitride film, and the insulating film; and
forming an opening connected to the insulating film in the top nitride film and performing wet etching using the formed opening.

12. The method of claim 11, wherein
forming of the first and second wires is performed by:
forming a barrier metal film covering bottom surfaces of the first and second wiring trenches and side surfaces of the side nitride film; and
forming metal wires on the barrier metal film, and
the barrier metal film is one of a Ti film, a TiN film, and a stacked film of the Ti film and the TiN film.

13. The method of claim 11, wherein a guard ring surrounding the first and second wires is formed.

14. The method of claim 11, wherein the opening is formed on top portions between the adjacent wires in the top nitride film.

15. The method of claim 13, wherein the opening is formed outside of the first and second wires and inside of the guard ring.

16. The method of claim 14, wherein an air gap film is formed on the air gaps and on the top nitride film in order to close the opening.
